(19) United States
(12) Patent Application Publication
(10) Pub. No.: US 2026/0248048 A1
(43) Pub. Date: Aug. 20, 2026

(54) SEMICONDUCTOR PACKAGE INCLUDING INTEGRATED VOLTAGE REGULATOR AND CAPACITOR

(71) Applicant: Samsung Electronics Co., Ltd., Suwon-si (KR)

(72) Inventors: Masayuki Miura, Yokohama (JP); Ryuichiro Tominaga, Yokohama (JP)

(21) Appl. No.: 19/427,537

(22) Filed: Dec. 19, 2025

(30) Foreign Application Priority Data
Feb. 17, 2025 (JP) 2025-23498
May 9, 2025 (KR) 10-2025-0060678

(51) Int. Cl. H10W 90/00; H10D 1/68; H10W 44/00; H10W 70/60; H10W 72/00; H10W 90/22; H10B 80/00; H10D 80/30; H10W 90/10

(52) U.S. Cl. CPC H10W 90/401; H10D 1/68; H10W 44/501; H10W 70/614; H10W 72/823; H10W 90/22; H10B 80/00; H10D 80/30; H10W 90/10; H10W 90/728

(57) ABSTRACT

A semiconductor package as an integrated voltage regulator (IVR) package having high voltage conversion efficiency and capable of miniaturization of electronic equipment. The semiconductor package includes an interposer including an integrated voltage regulator (IVR) chip and a first capacitor in the interposer, wherein the interposer includes a core layer having a first surface and a second surface opposite to the first surface, a first wiring layer formed on the first surface of the core layer, a second wiring layer formed on the second surface of the core layer, and a through-hole conductor electrically connected to the first wiring layer and the second wiring layer, and configured to penetrate from the first surface to the second surface, wherein at least a portion of each of the IVR chip and the first capacitor overlap with each other in a vertical direction.

### CROSS-REFERENCE TO RELATED APPLICATION(S)

This application is based on and claims priority under 35 U.S.C. § 119 to Japanese Patent Application No. 2025-23498, filed on February 17, 2025, in the Japan Intellectual Property Office, and to Korean Patent Application No. 10-2025-0060678, filed on May 09, 2025, in the Korean Intellectual Property Office, the disclosure of both of which are incorporated by reference herein in their entireties.

### BACKGROUND

The inventive concept relates to a semiconductor package.

Voltage regulators (VRs) are widely used for supplying constant voltages to electronic devices, such as computers, servers, and smartphones. Inductors and capacitors are required for operations of the VRs, and in general, the VRs, inductors, and capacitors are mounted on substrates. In this case, there is an issue in that sizes of the electronic devices increase due to the increase of mounting areas. As a solution for this issue, an integrated voltage regulator (IVR) in which voltage regulators, inductors, and capacitors are accommodated in one package is disclosed. Patent Document 1 (Japan Patent Publication No. 2012-079718) discloses a voltage conversion module, and Patent Document 2 (Japan Patent Publication No. 2023-116418) discloses an IVR package including inductors and capacitors.

### SUMMARY

The inventive concept provides a semiconductor package as an integrated voltage regulator (IVR) package having high voltage conversion efficiency and capable of miniaturization of electronic devices.

In addition, the issues to be solved by the technical idea of the inventive concept are not limited to those mentioned above, and other issues may be clearly understood by those of ordinary skill in the art from the following descriptions.

According to an aspect of the inventive concept, there is provided a semiconductor package including an interposer including an integrated voltage regulator (IVR) chip and a first capacitor in the interposer, wherein the interposer includes a core layer having a first surface and a second surface opposite to the first surface, a first wiring layer formed on the first surface of the core layer, a second wiring layer formed on the second surface of the core layer, and a through-hole conductor electrically connected to the first wiring layer and the second wiring layer, and configured to penetrate the core layer from the first surface to the second surface, wherein the IVR chip and the first capacitor are surrounded by the through-hole conductor, and wherein the IVR chip and the first capacitor at least partially overlap each other in a vertical direction.

In addition, according to another aspect of the inventive concept, there is provided a semiconductor package including a package substrate, an interposer arranged on the package substrate and including an integrated voltage regulator (IVR) chip and a first capacitor inside the interposer, a logic chip on the interposer, and a memory chip adjacent to the logic chip and mounted on the interposer, wherein the interposer includes a core layer having a first surface and a second surface opposite to the first surface, a first wiring layer formed on the first surface of the core layer, a second wiring layer formed on the second surface of the core layer, and a through-hole conductor electrically in contact with the first wiring layer and the second wiring layer, and configured to penetrate the core layer from the first surface to the second surface, and wherein at least a portion of each of the IVR chip and the first capacitor overlap with each other in a vertical direction that is perpendicular to an upper surface of the package substrate.

Furthermore, according to another aspect of the inventive concept, there is provided a semiconductor package including a package substrate including an inductor therein, an interposer arranged on the package substrate and including an integrated voltage regulator (IVR) chip and a first capacitor inside the interposer, a logic chip on the interposer, and a memory chip adjacent to the logic chip and mounted on the interposer, wherein the interposer includes a core layer having a first surface and a second surface opposite to the first surface, a first wiring layer formed on the first surface of the core layer, a second wiring layer formed on the second surface of the core layer, and a through-hole conductor electrically connected to the first wiring layer and the second wiring layer, and configured to penetrate the core layer from the first surface to the second surface, wherein the IVR chip and the first capacitor are arranged inside the interposer between the first wiring layer and the second wiring layer, and wherein at least a portion of each of the inductor, the IVR chip, the first capacitor, and the logic chip overlap with each other in a vertical direction that is perpendicular to an upper surface of the package substrate.

### BRIEF DESCRIPTION OF THE DRAWINGS

FIG. 1 is a cross-sectional view of a semiconductor package according to an example embodiment;

FIG. 2 is a plan view of an interposer in the semiconductor package of FIG. 1;

FIG. 3 is a cross-sectional view of a semiconductor package according to an example embodiment;

FIG. 4 is a cross-sectional view of a semiconductor package according to an example embodiment;

FIG. 5 is an enlarged cross-sectional view of region V in the semiconductor package of FIG. 4;

FIG. 6 is a cross-sectional view of a semiconductor package according to an example embodiment; and

FIG. 7 is a cross-sectional view of a semiconductor package according to an example embodiment.

### DETAILED DESCRIPTION OF THE EMBODIMENTS

Hereinafter, embodiments of the inventive concept will be described in detail with reference to the accompanying drawings. Identical reference numerals are used for the same constituent elements in the drawings, and duplicate descriptions thereof are omitted.

For reference, a voltage conversion module of Patent Document 1 (Japan Patent Publication No. 2012-079718) may be equipped with a multilayer wiring board including a plurality of wiring patterns, a voltage conversion integrated circuit (IC) mounted on one of inner layers of the plurality of wiring patterns, a first condenser electrically connected to the voltage conversion IC, a second condenser electrically connected to the voltage conversion IC, and an inductor mounted to be adjacent to the second condenser and electrically connected to the voltage conversion IC.

In addition, an integrated voltage regulator (IVR) package of Patent Document 2 (Japan Patent Publication No. 2023-116418) may be equipped with a package substrate, a stacked structure system having a stacked structure including a passive device chip including a capacitor and an IVR chip, which are mounted on the package substrate, and an intermediary substrate arranged on the package substrate, having a structure surrounding the stacked structure system, and including a via therein, and an inductor may be included in the stacked structure system or the intermediary substrate.

As used herein, terms such as “same,” “equal,” “planar,” or “coplanar,” when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

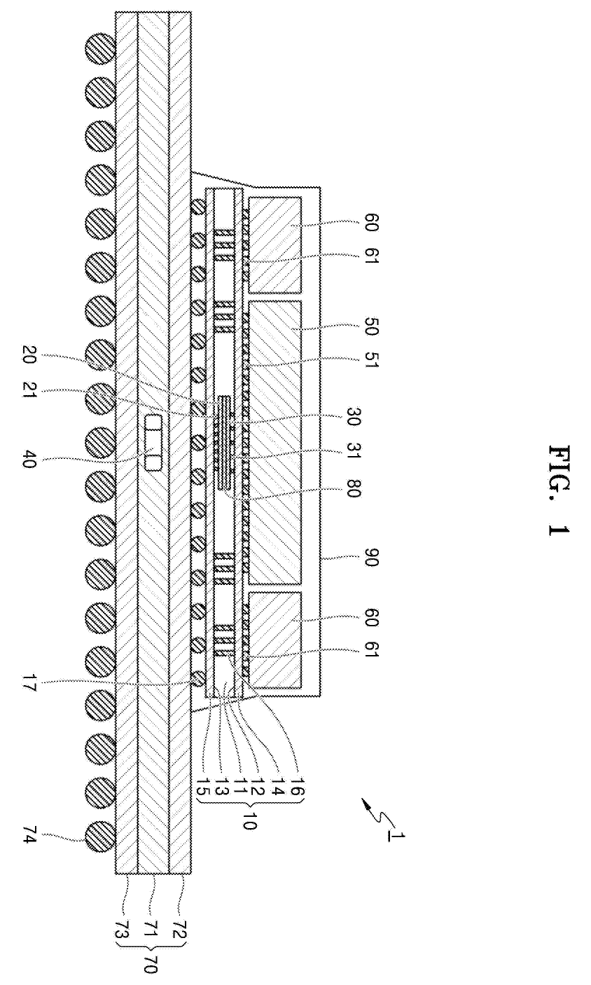

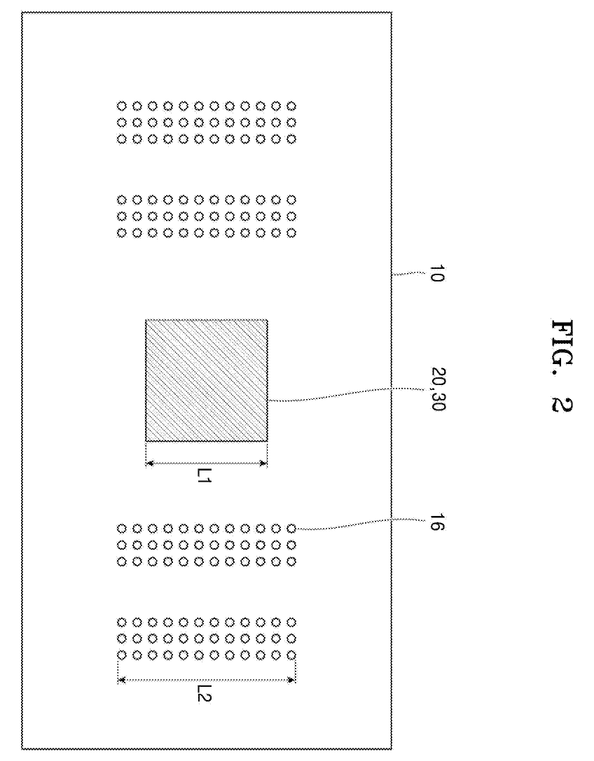

FIG. 1 is a cross-sectional view of a semiconductor package 1 according to an example embodiment, and FIG. 2 is a plan view of an interposer 10 in the semiconductor package 1 of FIG. 1.

Referring to FIGS. 1 and 2, the semiconductor package 1 of the present embodiment may include the interposer 10, an integrated voltage regulator (IVR) chip 20, a first capacitor 30, an inductor 40, a logic chip 50, memory chips 60, a package substrate 70, and an encapsulation resin 90.

The interposer 10 may include a substrate for electrically connecting a plurality of chips. The interposer 10 may include a core layer 11 including resin. A first wiring layer 14 may be formed on a first surface 12 of the core layer 11, and a second wiring layer 15 may be formed on a second surface 13 of the core layer 11. The first surface 12 and the second surface 13 may be opposite surfaces of the core layer 11.

The interposer 10 may include through-hole conductors 16 penetrating from the first surface 12 to the second surface 13 of the core layer 11. For example, upper surfaces of the through-hole conductors 16 may be coplanar with the first surface 12, and lower surfaces of the through-hole conductors 16 may be coplanar with the second surface 13. The through-hole conductors 16 may be electrically connected to the first wiring layer 14 and the second wiring layer 15. For example, upper surfaces of the through-hole conductors 16 may be in contact with the first wiring layer 14, and lower surfaces of the through-hole conductors 16 may be in contact with the second wiring layer 15. In addition, the interposer 10 may include a first bump 17 as an example of an electrode on the outside of the second wiring layer 15. In example embodiments, the interposer 10 may include a plurality of first bumps 17. The interposer 10 may be mounted on the package substrate 70 to be described below by using the first bumps 17.

The IVR chip 20 may include a voltage regulator, and may supply a constant voltage to an electronic device mounted on the interposer 10. For example, the IVR chip 20 may convert, regulate, and supply voltages to electronic devices mounted on the interposer 10, including, for example, a logic chip 50 and memory chips 60. The IVR chip 20 may control a voltage by repeating ON/OFF operations on a switch device. The switch device may include, for example, a metal-oxide semiconductor field effect transistor (MOSFET). The IVR chip 20 may be mounted face-down inside the interposer 10, and may be electrically connected to the second wiring layer 15 via second bumps 21. For example, the IVR chip 20 may be mounted such that the active surface of the IVR chip 20 faces the second wiring layer 15. The active surface of the IVR chip 20 may be the surface on which devices are formed.

The first capacitor 30 may include a device required for an operation of the IVR chip 20. The purpose of the first capacitor 30 may be storing charges, and may be connected to a reference potential such as a ground voltage (GND) and/or a negative power source of a field effect transistor (FET) such as a common ground voltage (VSS). The first capacitor 30 may have a large capacitance to prevent fluctuations in the power voltage and/or to absorb ripple noise. A thin film capacitor, a silicon capacitor, or the like may be used for the first capacitor 30.

The first capacitor 30 may be stacked on the IVR chip 20, and the first capacitor 30 and the IVR chip 20 may form a stacked structure. For example, the first capacitor 30 may be disposed on the inactive surface of the IVR chip 20. In some embodiments, the first capacitor 30 may be stacked directly on the IVR chip 20. However, in other embodiments, the first capacitor 30 may be stacked on the IVR chip 20 with an adhesive layer 80 therebetween. In example embodiments, the inactive surfaces of the first capacitor 30 and the IVR chip 20 may contact the adhesive layer 80. The first capacitor 30 may be mounted face-up inside the interposer 10, and may be electrically connected to the first wiring layer 14 via third bumps 31. For example, the first capacitor 30 may be mounted such that the active surface of the first capacitor 30 faces the first wiring layer 14, and the third bumps 31 may contact the first capacitor 30 and the first wiring layer 14. The active surface of the first capacitor 30 may be the surface on which devices are formed. On the other hand, in FIG. 1, the IVR chip 20 and the first capacitor 30 may be stacked in a completely overlapping structure, but are not limited thereto, and may be stacked in a partially overlapping structure. The IVR chip 20 and the first capacitor 30 may be surrounded by the core layer 11.

The inductor 40 may be a device required for the operation of the IVR chip 20 together with the first capacitor 30. When current flows in the inductor 40, power loss may occur due to resistance therein, voltage conversion efficiency may decrease, and at the same time, heat may be generated due to the power loss. Accordingly, less resistance of the inductor 40 may be better. To reduce the resistance of the inductor 40, the cross-sectional area of the conductor constituting the inductor 40 may be increased. Accordingly, the size of the inductor 40 may tend to increase.

Because the size of the entire package increases when the inductor 40 of a large size is mounted inside the interposer 10, the inductor 40 may be mounted inside the package substrate 70 which is spatially sufficient. By embedding the inductor 40 inside the package substrate 70, miniaturization of the semiconductor package 1 may be implemented. The inductor 40 may be arranged to overlap the IVR chip 20 and the first capacitor 30 in a plan view. In this case, the plan view may mean a state in which the semiconductor package 1 is viewed from the logic chip 50 toward the package substrate 70 in FIG. 1. In other words, the inductor 40 may be arranged to overlap the IVR chip 20 and the first capacitor 30 in a vertical direction that is perpendicular to the upper surface of the package substrate 70.

When the IVR chip 20, the first capacitor 30, and the inductor 40 are arranged horizontally in a horizontal direction that is parallel with the upper surface of the package substrate 70, the distances between them may be increased. However, because at least one of the first capacitor 30 and the inductor 40 overlaps the IVR chip 20 in the vertical direction, the distances between them may be decreased, and thus the parasitic capacitance or parasitic resistance thereof may be decreased. As a result, the operating characteristics of the IVR chip 20 may be improved, and thus the voltage conversion efficiency thereof may be improved.

In FIG. 1, the inductor 40 may be arranged to completely overlap the IVR chip 20 and the first capacitor 30 in a plan view. In other words, the inductor 40 may be arranged to completely overlap the IVR chip 20 and the first capacitor 30 in the vertical direction. However, the embodiment is not limited thereto, and the voltage conversion efficiency may also be improved in a state in which a portion of each component is partially overlapped in the vertical direction.

The logic chip 50 may include a plurality of logic devices therein. The logic devices are, for example, AND, NAND, OR, NOR, exclusive OR (XOR), exclusive NOR (XNOR), inverter (INV), adder (ADD), buffer (BUF), delay (DLY), filter (FIL), multiplexer (MXT/MXIT), OR/AND/INVERTER (OAI), AND/OR (AO), AND/OR/INVERTER (AOI), a D flip-flop, a reset flip-flop, a master-slave flip-flop, a latch, a counter, or buffer elements. Logic devices may perform various signal processing, such as analog signal processing, analog-to-digital (A/D) conversion, and control.

The logic chip 50 may be referred to as a central processing unit (CPU) chip, a micro-processor unit (MPU) chip, a graphics processing unit (GPU) chip, a natural processing unit (NPU) chip, a digital signal processor (DSP) chip, a system on glass (SOG) chip, an application specific integrated circuit (ASIC) chip, or a control chip, depending on its function.

The logic chip 50 may be mounted face-down on the first wiring layer 14 of the interposer 10, and may be electrically connected to the first wiring layer 14 via a fourth bump 51. For example, an active surface of the logic chip 50 may face the first wiring layer 14 of the interposer 10. The active surface of the logic chip 50 may be the surface on which devices are formed. The logic chip 50 may be arranged to overlap the IVR chip 20 in a plan view. In other words, the logic chip 50 may be arranged to overlap the IVR chip 20 in the vertical direction. Because the logic chip 50 consuming a large amount of current overlaps the IVR chip 20 in the vertical direction, the distance therebetween may be shortened, and thus the power efficiency may be improved. In addition, by overlapping the logic chip 50 and the IVR chip 20 in the vertical direction, it may be possible to miniaturize a size of an electronic equipment.

In FIG. 1, the logic chip 50 may be arranged to overlap the IVR chip 20 and the first capacitor 30 in a plan view. However, the embodiment is not limited thereto, and the power efficiency may also be improved in a state in which a portion of each component is partially overlapped in the vertical direction. In this case, the state in which at least a portion of each component is overlapped may mean a state in which a portion of the IVR chip 20 and a portion of the first capacitor 30 overlap with each other in a plan view, and another portion of the IVR chip 20 or another portion of the first capacitor 30 and a portion of the logic chip 50 overlap with each other. In addition, in some embodiments, all three portions, that is, a portion of the IVR chip 20, a portion of the first capacitor 30, and a portion of the logic chip 50 may overlap together in a plan view.

In addition, in a plan view, at least portions of the inductor 40, the IVR chip 20, the first capacitor 30, and the logic chip 50 may partially overlap each other. This state may be obtained by overlapping a portion of the inductor 40 with any one of the IVR chip 20, the first capacitor 30, and the logic chip 50 in a plan view, in addition to portions where the IVR chip 20, the first capacitor 30, and the logic chip 50 overlap each other. In addition, in some embodiments, all four portions, that is, a portion of the inductor 40, a portion of the IVR chip 20, a portion of the first capacitor 30, and a portion of the logic chip 50 may overlap together in a plan view.

The memory chips 60 may include, for example, a high bandwidth memory (HBM). However, the memory chips 60 are not limited to the HBM. At least one of the memory chips 60 may be mounted adjacent to the logic chip 50 on the interposer 10. The memory chips 60 may be mounted face-down on the interposer 10, and may be electrically connected to the first wiring layer 14 via fifth bumps 61. The fifth bumps 61 may contact the active surfaces of the memory chips 60. For example, active surfaces of the memory chips 60 may face the first wiring layer 14. The active surfaces of the memory chips 60 may be the sides on which devices are formed. In addition, while two memory chips 60 are illustrated, embodiments may include a single memory chip 60 or three or more memory chips 60.

The package substrate 70 may extend an electrode (the first bump 17) of the interposer 10 to the outside region and rewire it. For example, the package substrate 70 may provide wiring that connects the first bumps 17 of the interposer 10 to the outside of the semiconductor package 1. The package substrate 70 may include a core layer 71 including a resin, a third wiring layer 72 formed on an upper surface of the core layer 71, and a fourth wiring layer 73 formed on a lower surface of the core layer 71. External connection terminals 74 for mounting the semiconductor package 1 on an external system substrate or a main board may be formed on a lower surface of the fourth wiring layer 73 of the package substrate 70. In example embodiments, the external connection terminals 74 may contact the lower surface of the fourth wiring layer 73. The interposer 10 may be electrically connected to the third wiring layer 72 of the package substrate 70 by using the first bumps 17 formed on a lower surface of the second wiring layer 15.

FIG. 2 is a plan view of the interposer 10 of the semiconductor package 1 of FIG. 1. The through-hole conductors 16 may be formed on the left and right sides of the IVR chip 20 and the first capacitor 30. For example, the through-hole conductors 16 may be formed on opposite sides of the IVR chip 20 and the first capacitor 30. In example embodiments, the through-hole conductors 16 may be formed on the same sides on which the memory chips 60 are formed. In the example illustrated in FIG. 2, two pairs of three-by-twelve (3x12) through-hole conductors 16 may be formed on each of the left side and the right side of the IVR chip 20 and the first capacitor 30. However, the arrangement or quantity of the through-hole conductors 16 is not limited thereto. The state in which the IVR chip 20 and the first capacitor 30 are surrounded by the through-hole conductors 16 may mean a state in which the through-hole conductors 16 are formed in at least two opposite directions of the IVR chip 20 and the first capacitor 30. The through-hole conductors 16 may be formed on the left and right sides of the IVR chip 20 and the first capacitor 30. In other words, the IVR chip 20 and the first capacitor 30 may be surrounded by the through-hole conductors 16 from the left side to the right side thereof. When the length of the sides of the IVR chip 20 and the first capacitor 30 facing the through-hole conductors 16 is defined as L1, and the length of the region in which the through-hole conductors 16 are formed is defined as L2, it may be understood that L1 ≤ L2. In this case, the length of the region in which the through-hole conductors 16 are formed may mean the distance between the through-hole conductors 16, which are farthest from each other, in a direction along the sides of the IVR chip 20 and the first capacitor 30.

Because the IVR chip 20 and the first capacitor 30 are surrounded by the through-hole conductors 16 in at least two opposite directions, ripple noise generated during the switching operation of the IVR chip 20 may be reduced. In addition, the IVR chip 20 and the first capacitor 30 may be surrounded from the top side and the bottom side by the first wiring layer 14 and the second wiring layer 15 of the interposer 10 (refer to FIG. 1). Accordingly, the ripple noise may be further decreased.

For reference, in a general IVR package structure, because IVR chips are far from devices, such as the CPU and the GPU, which consume a large amount of current, there may be an issue that the voltage conversion efficiency of the IVR chip is poor. In addition, there may be another issue that because the size of an inductor needs to be increased to lower the resistance thereof, the IVR package becomes larger. However, the semiconductor package 1 of the present embodiment may solve all of the aforementioned issues, by arranging at least portions of each of the IVR chip 20, the first capacitor 30, the inductor 40, and the logic chip 50 in a structure in which they overlap with each other in the vertical direction.

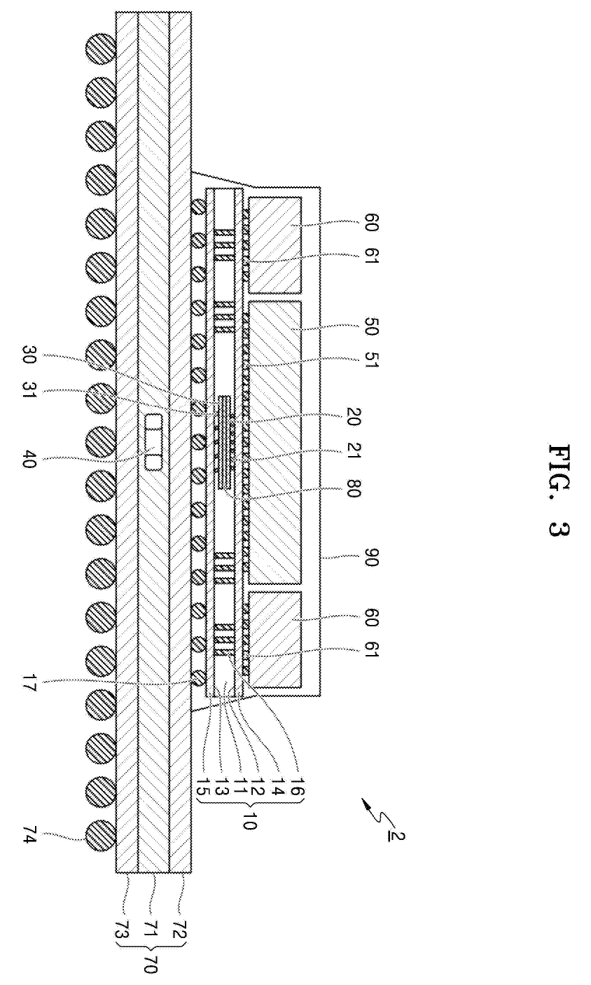

FIG. 3 is a cross-sectional view of a semiconductor package 2 according to an example embodiment. Duplicate descriptions already given with reference to FIGS. 1 and 2 are briefly described or not repeated.

Referring to FIG. 3, the semiconductor package 2 of the present embodiment may be the same as the semiconductor package 1 of FIG. 1, except for an aspect of a mounting state of the IVR chip 20 and the first capacitor 30. For example, in the semiconductor package 1 of FIG. 1, the IVR chip 20 may be mounted face-down, and the first capacitor 30 may be mounted face-up. On the other hand, in the semiconductor package 2 of the present embodiment, the first capacitor 30 may be mounted face-down, and the IVR chip 20 may be mounted face-up.

In the semiconductor package 2 of the present embodiment, the first capacitor 30 may be mounted face-down inside the interposer 10, and may be electrically connected to the second wiring layer 15 via the third bumps 31. For example, the first capacitor 30 may be mounted such that the active surface of the first capacitor 30 faces the second wiring layer 15. The IVR chip 20 may be stacked on the first capacitor 30. For example, the IVR chip 20 may be disposed on the inactive surface of the first capacitor 30. In some embodiments, the IVR chip 20 may be directly stacked on the first capacitor 30. However, in other embodiments, the IVR chip 20 may be stacked on the first capacitor 30 with the adhesive layer 80 therebetween. The IVR chip 20 may be mounted face-up inside the interposer 10, and may be electrically connected to the first wiring layer 14 via the second bumps 21. For example, the IVR chip 20 may be mounted such that the active surface of the IVR chip 20 faces the first wiring layer 14.

In a plan view, at least portions of each of the inductor 40, the IVR chip 20, the first capacitor 30, and the logic chip 50 may partially overlap each other. A state in which at least portions of each of them partially overlap each other may be a state in which a portion of the IVR chip 20 and a portion of the first capacitor 30 overlap each other in a plan view, another portion of the IVR chip 20, or another portion of the first capacitor 30 and a portion of the logic chip 50 overlap each other, and in addition, a portion of the inductor 40 overlaps any one of the IVR chip 20, the first capacitor 30, and the logic chip 50. In addition, in some embodiments, all four portions, that is, a portion of the inductor 40, a portion of the IVR chip 20, a portion of the first capacitor 30, and a portion of the logic chip 50 may overlap together in a plan view.

Similar to the semiconductor package 1 of FIG. 1, the semiconductor package 2 of the present embodiment may have improvement of voltage conversion efficiency, improvement of power efficiency, reduction in ripple noise, and miniaturization of electronic equipment.

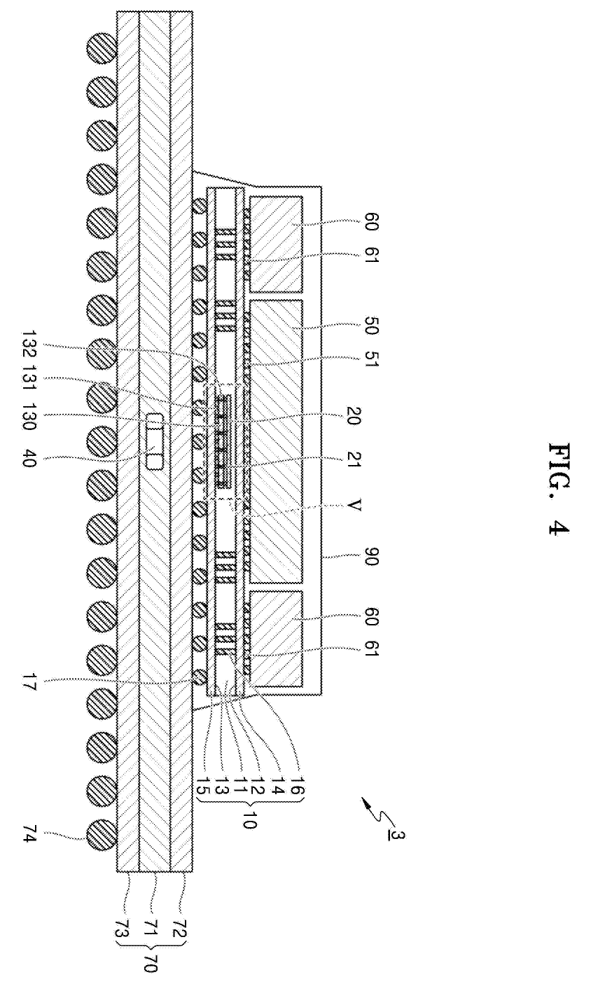

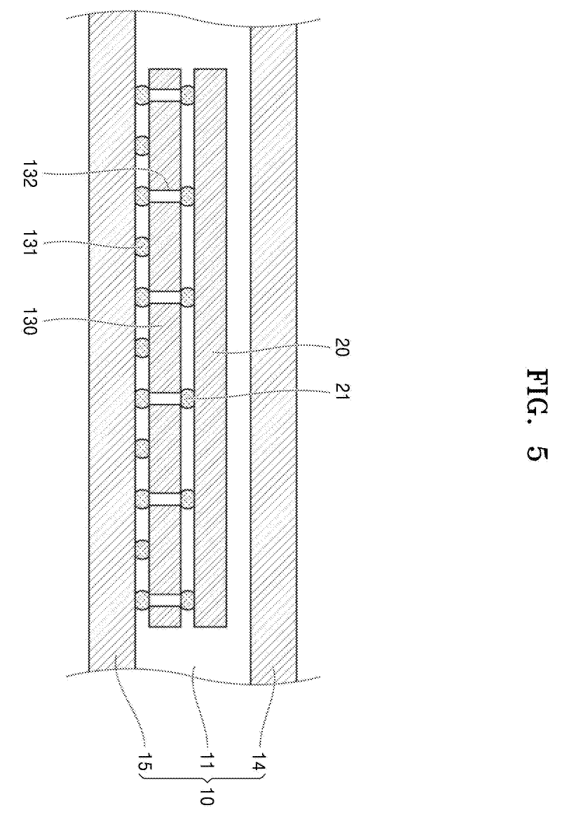

FIG. 4 is a cross-sectional view of a semiconductor package 3 according to an example embodiment, and FIG. 5 is an enlarged cross-sectional view of region V in the semiconductor package 3 of FIG. 4. Duplicate descriptions already given with reference to FIGS. 1 through 3 are briefly described or not repeated.

Referring to FIGS. 4 and 5, the semiconductor package 3 of the present embodiment may be the same as the semiconductor package 1 of FIG. 1, except for a mounting state of a first capacitor 130. In the semiconductor package 3, the first capacitor 130 may have a different shape from the first capacitor 30 of the semiconductor package 1 of FIG. 1. However, the first capacitor 130 may be used for the same purpose of the first capacitor 30 of the semiconductor package 1 of FIG. 1. Accordingly, the first capacitor 130 may have the same capacitance as the first capacitor 30.

The first capacitor 130 may be mounted face-down inside the interposer 10, and may be electrically connected to the second wiring layer 15 via third bumps 131. For example, the active surface of the first capacitor 130 may face the second wiring layer 15, and the third bumps 131 may contact the first capacitor 130 and the second wiring layer 15. Through electrodes 132 may be formed in the first capacitor 130, and the through electrodes 132 may be electrically connected to the second wiring layer 15 via the third bumps 131. In example embodiments, upper surfaces of the through electrodes 132 may be coplanar with the inactive surface of the first capacitor 130, and lower surfaces of the through electrodes 132 may be coplanar with the active surface of the first capacitor 130. The third bumps 131 may contact lower surfaces of the through electrodes 132, respectively. The IVR chip 20 may be stacked on the first capacitor 130. The IVR chip 20 may be mounted face-down on the first capacitor 130 by using the second bumps 21. For example, the active surface of the IVR chip 20 may face the first capacitor 130. The IVR chip 20 may be electrically connected to the through electrodes 132 of the first capacitor 130 via the second bumps 21. Accordingly, the IVR chip 20 may be electrically connected to the second wiring layer 15 of the interposer 10 via the second bumps 21, the through electrodes 132, and the third bumps 131.

Similar to the semiconductor package 1 of FIG. 1, the semiconductor package 3 of the present embodiment may have improvement of voltage conversion efficiency, improvement of power efficiency, reduction in ripple noise, and miniaturization of electronic equipment.

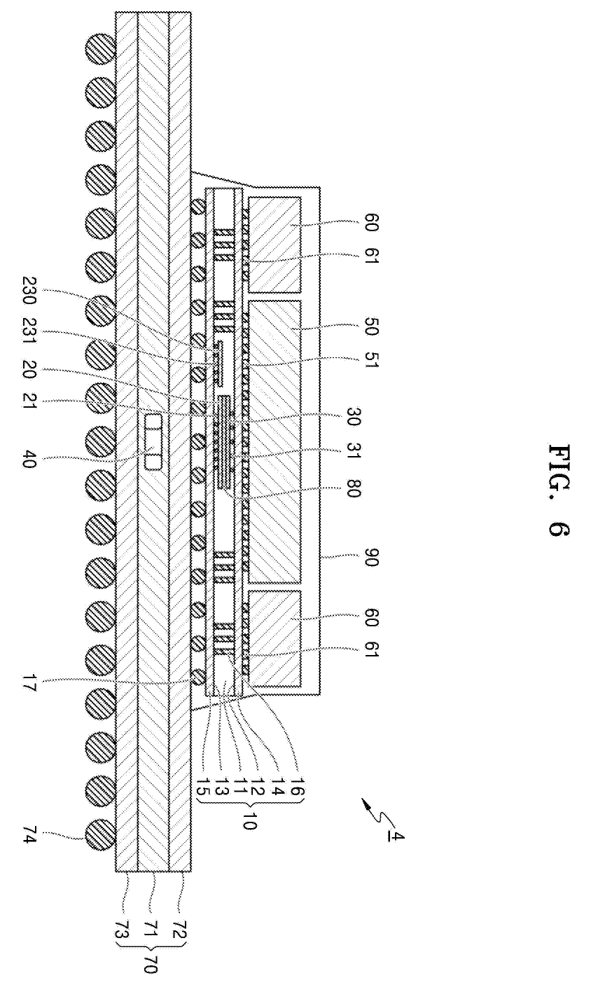

FIG. 6 is a cross-sectional view of a semiconductor package 4 according to an example embodiment. Descriptions already given with reference to FIGS. 1 through 5 are briefly described or not repeated.

Referring to FIG. 6, the semiconductor package 4 of the present embodiment may be the same as the semiconductor package 1 of FIG. 1, except that the semiconductor package 4 includes a second capacitor 230. In the semiconductor package 4 of the present embodiment, the second capacitor 230 may be arranged adjacent to the first capacitor 30 inside the interposer 10. For example, the second capacitor 230 may be arranged inside the interposer 10 adjacent to a stacked structure of the first capacitor 30 and the IVR chip 20. For example, the second capacitor 230 may be arranged to a side of the stacked structure of the first capacitor 30 and the IVR chip 20 in a horizontal direction inside the interposer 10. The second capacitor 230 may be mounted face-down inside the interposer 10, and may be electrically connected to the second wiring layer 15 via sixth bumps 231. For example, the active surface of the second capacitor 230 may face the second wiring layer 15. The sixth bumps 231 may contact the second capacitor 230 and the second wiring layer 15.

The primary purpose of the second capacitor 230 may be transmission of charges, and because the second capacitor 230 is connected to a terminal at which a potential is not fixed, the second capacitor 230 may be referred to as a flying capacitor. For example, the second capacitor 230 may be connected to a transistor and may be used to reduce ripple noise. The capacitance of the second capacitor 230 may be less than that of the first capacitor 30.

The semiconductor package 4 of the present embodiment may not only obtain the same effect as the semiconductor package 1 of FIG. 1, but may also reduce noise by further including the second capacitor 230.

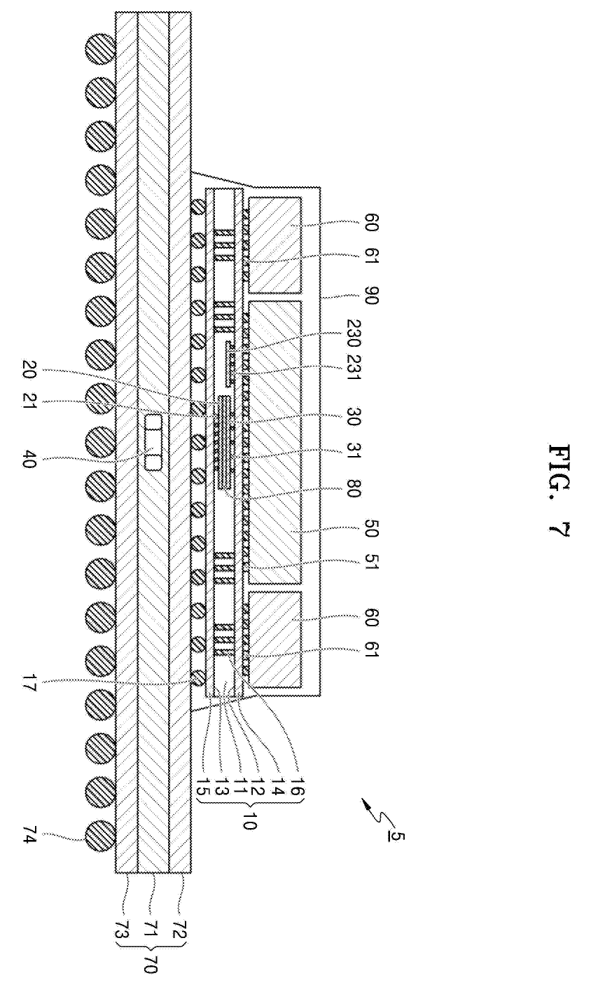

FIG. 7 is a cross-sectional view of a semiconductor package 5 according to an example embodiment. The contents already given with reference to FIGS. 1 through 6 are briefly described or not repeated.

Referring to FIG. 7, the semiconductor package 5 of the present embodiment may be the same as the semiconductor package 4 of FIG. 6, except for an aspect of mounting of the second capacitor 230. In the semiconductor package 4 of FIG. 6, the second capacitor 230 may be mounted face-down. In contrast, in the semiconductor package 5 according to the present embodiment, the second capacitor 230 may be mounted face-up.

In the semiconductor package 5 of the present embodiment, the second capacitor 230 may be arranged adjacent to the first capacitor 30 inside the interposer 10. For example, the second capacitor 230 may be arranged inside the interposer 10 adjacent to a stacked structure of the first capacitor 30 and the IVR chip 20. For example, the second capacitor 230 may be arranged to a side of the stacked structure of the first capacitor 30 and the IVR chip 20 in a horizontal direction inside the interposer 10. The second capacitor 230 may be mounted face-up inside the interposer 10, and may be electrically connected to the first wiring layer 14 via the sixth bumps 231. For example, the active surface of the second capacitor 230 may face the first wiring layer 14. The sixth bumps 231 may contact the second capacitor 230 and the first wiring layer 14.

The primary purpose of the second capacitor 230 may be transmission of charges, and because the second capacitor 230 is connected to a terminal at which a potential is not fixed, the second capacitor 230 may be referred to as a flying capacitor. For example, the second capacitor 230 may be connected to a transistor and may be used to reduce ripple noise. The capacitance of the second capacitor 230 may be less than that of the first capacitor 30.

The semiconductor package 5 of the present embodiment may obtain the same effect as the semiconductor package 4 of FIG. 6, but may also reduce noise by further including the second capacitor 230.

Although various embodiments have been described so far, the technical idea of the inventive concept is not limited to the scope described in the embodiments described above. It may be apparent from the description of the scope of the inventive concept that a combination of two or more of the embodiments described above or various changes or improvements in the embodiments are included in the technical idea of the inventive concept.

In an embodiment of the inventive concept, a logic chip mounted on the first wiring layer formed face-down on the first surface side of the core layer of the interposer may be further included, and in addition, at least portions of each of the logic chip, the IVR chip, and the first capacitor may overlap each other in a plan view.

In an embodiment of the inventive concept, the interposers may be mounted on a package substrate with an electrode formed on a surface of the second wiring layer formed on a second surface side of the core layer therebetween.

In an embodiment of the inventive concept, the package substrate may include an inductor embedded therein, and in addition, in a plan view, at least portions of each of the inductor, the IVR chip, the first capacitor, and the logic chip, which are embedded in the package substrate, may overlap each other.

In an embodiment of the inventive concept, the IVR chip may be mounted face-down on the second wiring layer, and in addition, may be electrically connected to the second wiring layer.

In an embodiment of the inventive concept, the first capacitor may be mounted face-up on the first wiring layer, and in addition, may be electrically connected to a first wiring layer.

In an embodiment of the inventive concept, the IVR chip and the first capacitor may have a structure in which they are stacked and are in contact with each other.

In an embodiment of the inventive concept, the IVR chip may be stacked on the first capacitor by using an adhesive layer.

In an embodiment of the inventive concept, the first capacitor may be mounted face-down on the second wiring layer, and in addition, may be electrically connected to the second wiring layer.

In an embodiment of the inventive concept, the first capacitor mounted face-down on the second wiring layer may include a through electrode.

In an embodiment of the inventive concept, the IVR chip may be mounted face-down on the first capacitor which is mounted face-down on the second wiring layer, and in addition, may be electrically connected to the second wiring layer via the through electrode.

In an embodiment of the inventive concept, the interposer may further include a second capacitor which is arranged therein adjacent to a stacked structure of the IVR chip and the first capacitor, and has a capacitance less than that of the first capacitor.

In an embodiment of the inventive concept, the second capacitor may be mounted face-down on the second wiring layer, and in addition, may be electrically connected to the second wiring layer.

In an embodiment of the inventive concept, the second capacitor may be mounted face-up on the first wiring layer, and in addition, may be electrically connected to the first wiring layer.

While the inventive concept has been particularly shown and described with reference to example embodiments thereof, it will be understood by one of ordinary skill in the art that various changes in shape and details may be made therein without departing from the spirit and scope of the inventive concept as defined by the following claims. Accordingly, the true scope of protection of the inventive concept should be determined by the technical idea of the following claims.

What is claimed is:

1. A semiconductor package comprising an interposer including an integrated voltage regulator (IVR) chip and a first capacitor in the interposer,
wherein the interposer comprises:
a core layer having a first surface and a second surface opposite to the first surface;
a first wiring layer formed on the first surface of the core layer;
a second wiring layer formed on the second surface of the core layer; and
a through-hole conductor electrically connected to the first wiring layer and the second wiring layer, and configured to penetrate the core layer from the first surface to the second surface,
wherein the IVR chip and the first capacitor are surrounded by the through-hole conductor, and
wherein the IVR chip and the first capacitor at least partially overlap each other in a vertical direction.

2. The semiconductor package of claim 1, further comprising:
a logic chip mounted face-down on the first wiring layer of the interposer,
wherein at least a portion of each of the logic chip, the IVR chip, and the first capacitor overlap with each other in the vertical direction.

3. The semiconductor package of claim 2, further comprising:
a package substrate arranged under the interposer,
wherein the interposer is mounted on the package substrate by using an electrode arranged under a lower surface of the second wiring layer.

4. The semiconductor package of claim 3,
wherein the package substrate comprises an inductor therein, and
wherein at least a portion of each of the inductor, the IVR chip, the first capacitor, and the logic chip overlap with each other in the vertical direction.

5. The semiconductor package of claim 4, wherein the IVR chip is mounted face-down on the second wiring layer, and is electrically connected to the second wiring layer.

6. The semiconductor package of claim 5, wherein the first capacitor is mounted face-up on the first wiring layer, and is electrically connected to the first wiring layer.

7. The semiconductor package of claim 6, wherein the IVR chip and the first capacitor are in contact with each other to constitute a stacked structure.

8. The semiconductor package of claim 6, wherein the first capacitor is stacked on the IVR chip by using an adhesive layer.

9. The semiconductor package of claim 4, wherein the first capacitor is mounted face-down on the second wiring layer, and is electrically connected to the second wiring layer.

10. The semiconductor package of claim 9, wherein the first capacitor comprises a through electrode.

11. The semiconductor package of claim 10, wherein the IVR chip is mounted face-down on the first capacitor, and is electrically connected to the second wiring layer via the through electrode.

12. The semiconductor package of claim 8, wherein the interposer further comprises a second capacitor, which is arranged inside the interposer and adjacent to a stacked structure of the IVR chip and the first capacitor, and has a lower capacitance than the first capacitor.

13. The semiconductor package of claim 12, wherein the second capacitor is mounted face-down on the second wiring layer, and is electrically connected to the second wiring layer.

14. The semiconductor package of claim 12, wherein the second capacitor is mounted face-up on the first wiring layer, and is electrically connected to the first wiring layer.

15. The semiconductor package of claim 2, further comprising:
a memory chip adjacent to the logic chip and mounted face-down on the first wiring layer of the interposer.

16. A semiconductor package comprising:
a package substrate;
an interposer arranged on the package substrate and including an integrated voltage regulator (IVR) chip and a first capacitor inside the interposer;
a logic chip on the interposer; and
a memory chip adjacent to the logic chip and mounted on the interposer,
wherein the interposer comprises:
a core layer having a first surface and a second surface opposite to the first surface;
a first wiring layer formed on the first surface of the core layer;
a second wiring layer formed on the second surface of the core layer; and
a through-hole conductor electrically connected to the first wiring layer and the second wiring layer, and configured to penetrate the core layer from the first surface to the second surface, and
wherein at least a portion of each of the IVR chip and the first capacitor overlap with each other in a vertical direction that is perpendicular to an upper surface of the package substrate.

17. The semiconductor package of claim 16,
wherein the first capacitor is mounted face-down on the second wiring layer, and the IVR chip is stacked on the first capacitor and mounted face-up on the first wiring layer, or
wherein the IVR chip is mounted face-down on the second wiring layer, and the first capacitor is stacked on the IVR chip and mounted face-up on the first wiring layer.

18. The semiconductor package of claim 16,
wherein the first capacitor is mounted face-down on the second wiring layer,
wherein the IVR chip is stacked on the first capacitor, and mounted face-up on the first wiring layer, and
wherein the first capacitor comprises a through electrode.

19. The semiconductor package of claim 16,
wherein an inductor is arranged inside the package substrate, and
wherein at least a portion of each of the inductor, the IVR chip, the first capacitor, and the logic chip overlap with each other in the vertical direction.

20. A semiconductor package comprising:
a package substrate including an inductor therein;
an interposer arranged on the package substrate, and including an integrated voltage regulator (IVR) chip and a first capacitor inside the interposer;
a logic chip on the interposer; and
a memory chip adjacent to the logic chip and mounted on the interposer,
wherein the interposer comprises:
a core layer having a first surface and a second surface opposite to the first surface;
a first wiring layer formed on the first surface of the core layer;
a second wiring layer formed on the second surface of the core layer; and
a through-hole conductor electrically connected to the first wiring layer and the second wiring layer, and configured to penetrate the core layer from the first surface to the second surface,
wherein the IVR chip and the first capacitor are arranged inside the interposer between the first wiring layer and the second wiring layer, and
wherein at least a portion of each of the inductor, the IVR chip, the first capacitor, and the logic chip overlap with each other in a vertical direction that is perpendicular to an upper surface of the package substrate.
